(19) United States
(12) Patent Application Publication
(10) Pub. No.: US 2025/0029831 A1
(43) Pub. Date: Jan. 23, 2025

(54) PROCESS AND APPARATUS FOR RADICAL ENHANCED VAPOR DEPOSITION

(71) Applicant: ASM IP Holding B.V., Almere (NL)

(72) Inventor: Tommi Tynell, Espoo (FI)

(21) Appl. No.: 18/772,365

(22) Filed: Jul. 15, 2024

Related U.S. Application Data
(60) Provisional application No. 63/527,353, filed on Jul. 18, 2023.

(51) Int. Cl. H01L 21/02; C23C 16/26; C23C 16/455; C23C 16/505; H01J 37/32

(52) U.S. Cl. CPC H01L 21/0228; C23C 16/26; C23C 16/45538; C23C 16/45544; C23C 16/505; H01J 37/32357; H01L 21/02211; H01L 21/0234; H01J 37/32082; H01J 2237/028; H01J 2237/332

(57) ABSTRACT

The present disclosure relates to methods and systems for forming a radical treated film on a surface of a substrate. More particularly, the disclosed methods and systems utilize radical treatment to treat a film which has been deposited on the surface of a substrate. The radical treatment takes place in a radical treatment chamber and the deposition takes place in a deposition chamber, wherein the chambers are operationally coupled to allow a substrate to be transferred between them without any air break.

### CROSS-REFERENCE TO RELATED APPLICATIONS

This application claims priority to and the benefit of U.S. Provisional Application No. 63/527,353, filed Jul. 18, 2023, the entirety of which is incorporated by reference herein.

### FIELD OF INVENTION

The present disclosure relates to methods and systems for depositing a thin film on the surface of a substrate using plasma enhanced atomic-layer deposition (PEALD), and in particular to the use of radical enhanced atomic-layer deposition (REALD) for depositing a thin film on the substrate.

### BACKGROUND OF THE DISCLOSURE

Plasma-enhanced ALD (PEALD) may be used to overcome some of the limitations of thermal ALD processes. In these methods, a plasma is employed during at least one of the reaction steps. The use of energetic plasma species, such as radicals, as reactants increases the reactivity, allows for lower temperature processing and, in many instances, provides improved film properties (e.g., density, impurity level, and electronic properties). Various reactor configurations may be employed to influence the types and density of the plasma species that interact with the substrate. In direct PEALD, a plasma is created in close proximity to the substrate surface. The flux of energetic species (e.g., ions, radicals, etc.) can be high allowing for uniform film formation and short plasma exposure times, but plasma induced damage and anisotropy in the film can also occur. In contrast, in radical enhanced ALD (REALD), which is a type of PEALD utilizing a remote plasma source, ions are prevented from reaching the substrate surface and film growth relies only on the reactive radicals in the plasma. This approach avoids the plasma induced damage and anisotropy often associated with PEALD processes, while still providing an advantage in reactivity over thermal ALD processing.

Plasma-enhanced atomic layer deposition (PEALD) is widely used in the semiconductor industry due to its ability to utilize energetic ions in depositing high-quality film from a wide range of precursor chemicals under relatively mild conditions. However, the inherent anisotropy of the method means that its applicability is limited in the most challenging device designs where film conformality is highly important. Radical-enhanced ALD (REALD) has been identified as a potential solution for conformal growth of high-quality films. Unlike ions, the radicals are not accelerated into the substrate surface, so radical processes generally result in conformal film deposition, with the expense of film quality compared to the PEALD process.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

An aspect of the present disclosure is a method for forming a radical treated film on a surface of a substrate. The method comprises providing a substrate, and executing one or more super cycles. An individual super cycle comprises a deposition step and a radical treatment step. The deposition step comprises feeding precursor in vapor phase into a deposition chamber to deposit a film onto the substrate. The radical treatment step comprises generating a remote plasma, obtaining a radical flow from the remote plasma and exposing the substrate to the radical flow in a radical treatment chamber. The deposition chamber and the radical treatment chamber are operationally coupled to allow a substrate to be transferred between them without any air break.

Another aspect of the disclosure is a system, for example an apparatus. The system comprises one or more process chambers, each process chamber comprising two or more stations, each station comprising an upper compartment and a lower compartment. The upper compartment is configured to contain a substrate during processing of the substrate. The lower compartment comprises a shared intermediate space between the two or more stations. The system further comprises a first transfer system configured to move a substrate from a first process chamber to a second process chamber in a wafer handling chamber, a second transfer system configured to move the substrate from a first station to a second station within the shared intermediate space of a process chamber, a first heating unit configured to control a first station temperature independently of a second station temperature, a pressure system comprising a pump and exhaust, the pressure system configured to maintain a common process chamber pressure in the two or more stations, and a controller comprising a processor that provides instructions to the apparatus to control a cycle of:
(a) placing a substrate in a first station;
(b) depositing a film on the substrate in the first station by a vapor deposition process;
(c) after depositing the film on the substrate, placing the first substrate in the second station;
(d) performing a radical treatment on the substrate by supplying reactive gas to the station to form a modified film; and repeating (a)-(d) in a cycle until a film of desired thickness is deposited on the substrate.

Yet another aspect of the disclosure is a method for film deposition. The method comprises the steps of:
(a) placing a substrate in a first station, the first station comprising an upper chamber and a lower chamber, wherein the lower chamber comprises a shared intermediate space between the first station, a second station, a third station, and a fourth station;
(b) contacting the substrate in the first station with a precursor, wherein the contacting with the precursor forms a first film layer on the first substrate;
(c) after contacting the substrate in the first station with the precursor, placing the substrate in the second station;
(d) performing a first radical treatment on the substrate by contacting the surface of the first film layer with a reactive gas;
(e) after performing the first radical treatment on the substrate, placing the substrate in the third station;
(f) contacting the substrate in the third station with the precursor, wherein the contacting with the precursor forms a second film layer on the first substrate;
(g) after contacting the substrate in the third station with the precursor, placing the substrate in the fourth station;
(h) performing a second radical on the substrate by contacting the surface of the second film layer with a reactive gas; and repeating (a)-(h) in a cycle until a film of desired thickness is deposited on the first substrate.

In these aspects, in some embodiments, the radical treated film comprises carbon.

In these aspects, in some embodiments, the deposition step comprises a plurality of deposition cycles.

In these aspects, in some embodiments, the radical flow is obtained from the remote plasma with an ion trap.

In these aspects, in some embodiments, an ion trap is provided in the reaction chamber between the remote plasma discharge and the substrate.

In these aspects, in some embodiments, the ion trap is an electrically grounded mesh plate.

In these aspects, in some embodiments, the remote plasma discharge is produced by gas-phase ionization of a gas with a radio frequency (RF) power of 500 W or less.

In these aspects, in some embodiments, the remote plasma discharge is produced by gas-phase ionization of a gas with a radio frequency (RF) power of 50 W or less.

In these aspects, in some embodiments, a temperature of the substrate is at least 40° C. and no more than 550° C.

In these aspects, in some embodiments, a temperature of the substrate is at least 100° C. and no more than 400° C.

In these aspects, in some embodiments, the first precursor comprises silicon.

In these aspects, in some embodiments, the first precursor is selected from the group consisting of: a silane, an alkyl silane, a halosilane, an aminosilane, a silicon alkoxide, a siloxane, and combinations thereof.

In these aspects, in some embodiments, the first precursor is selected from the group consisting of: silane, disilane, trisilane, dimethylsilane, diethylsilane, trimethylsilane, triethylsilane, dichlorosilane, diiodosilane, hexachlorodisilane, octachlorotrisilane bis(diethylamino)silane, bis(diethylamino)dimethylsilane diisopropylaminosilane, N-(diethylaminosilyl)-N-ethylethanamine, hexamethylcyclotrisilazane, tetraethylotrhosilicate, dimethoxydimethylsilane, trimethoxymethylsilane, tetramethylcyclotetrasiloxane, octamethylcyclotetrasiloxane, 1,1,3,5,5,7-hexamethylcyclotetrasiloxane, 1,3,5,7-tetramethylcyclotetrasiloxane, bis(diethoxysilyl)ethane, methoxypropyltrimethoxysilane, and combinations thereof.

In these aspects, in some embodiments, the first precursor comprises boron.

In these aspects, in some embodiments, the first precursor is selected from the group consisting of: a borane, an alkyl borane, a boron halide an aryl borane, a carborane, an amine borane, an amino borane, a borate ester, a borazine, triethylboron and combinations thereof.

In these aspects, in some embodiments, the first precursor is selected from a group consisting of: nido-carborane, ortho-carborane, ammonia borane, dimethylamine borane, trimethylamine borane, t-butylamine borane, tris(dimethylamino)borane, bromobis(diethylamino)borane, bromobis(dimethylamino)borane, triethyl boron, boron triiodide, boron tribromide, B-(cycloriborazanyl)amine borane, trimethyl borate, triethyl borate, borazine, 2,4,6-trichloroborazine, 2,4,6-tribromoborazine, diborazine, and combinations thereof.

In these aspects, in some embodiments, the remote plasma is selected from the group consisting of: an oxygen containing gas, a nitrogen containing gas, a hydrogen containing gas, and combinations thereof.

In these aspects, in some embodiments, the radical flow comprises one or more of oxygen radicals, nitrogen radicals, hydrogen radicals and combinations thereof.

In these aspects, in some embodiments, the radical treated film is selected from the group consisting of: silicon nitride, silicon oxynitride, silicon oxycarbonitride, silicon carbonitride, silicon carbide, silicon oxycarbide, silicon oxide, and combinations thereof.

In these aspects, in some embodiments, the radical treated film is selected from the group consisting of: boron nitride, boron carbide, borocarbonitride, boron oxide, and combinations thereof.

In these aspects, in some embodiments, the radical treated film is selected from the group consisting of: silicon oxycarbonitride, silicon carbonitride, boron nitride, boron carbonide, hydrogenated boron carbonitride, and combinations thereof.

### BRIEF DESCRIPTION OF THE DRAWING FIGURES

The accompanying drawings are incorporated into and form a part of the specification to illustrate several examples of the present disclosure. The figures presented herein are not meant to be actual views of any particular material, structure, or device, but are merely idealized representations that are used to describe embodiments of the disclosure. It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure. The drawings, together with the description, explain the principles of the disclosure. The drawings simply illustrate preferred and alternative examples of how the disclosure can be made and used and are not to be construed as limiting the disclosure to only the illustrated and described examples. Further features and advantages will become apparent from the following, more detailed, description of various aspects, embodiments, and configurations of the disclosure, as illustrated by the drawings referenced below.

FIG. 1 is a process diagram of an exemplary embodiment of the disclosure.

FIG. 2A illustrates a multi-process chamber module and process according to some embodiments herein.

FIG. 2B illustrates a dual-chamber module and process according to some embodiments herein.

FIG. 3 is a schematic presentation of a reactor assembly according to some embodiments of the present disclosure, wherein the plasma is produced in the upper portion of the reaction chamber.

FIG. 4 is a schematic presentation of a reactor assembly according to some embodiments of the present disclosure, wherein the plasma is produced upstream of the radical treatment chamber using a remote plasma unit (RPU).

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

As used herein, “atomic layer deposition”, abbreviated as “ALD”, refers to a method of depositing a film on a substrate by sequentially exposing its surface to alternate gas-phase reactants. In contrast to chemical vapor deposition, the different reactants are not simultaneously present in the reactor, but rather they are introduced as a series of sequential, non-overlapping pulses. In each of these pulses, the reactant reacts with the surface in a self-limiting way or a substantially self-limiting way. Further, ALD, as used herein, may also be meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of reactants.

As used herein, “boron carbide” or “BₓC_{y}” refers to a material that comprises boron and carbon. In some embodiments, boron carbide may not include significant proportions of elements other than boron and carbon. In some embodiments, the boron carbide comprises B₄C. In some embodiments, the boron carbide may consist essentially of B₄C. In some embodiments, the boron carbide may not include stoichiometric boron carbide. In some cases, the boron carbide can include other elements, such as hydrogen.

As used herein, “boron carbonitride” or “BₓC_{y}N_{z}” refers to a material that that comprises boron, carbon, and nitrogen. Boron carbonitride may be represented by the formula BₓC_{y}N_{z} where the sum of x, y, and z is equal to 3. In some cases, the boron carbonitride may include other elements, such as hydrogen. The boron carbonitride may include boron carbide and boron nitride.

As used herein, “boron oxycarbide” or “BₓO_{y}C_{y}” refers to a material that that comprises boron, oxygen and carbon. In some embodiments, boron oxide may not include significant proportions of elements other than boron, oxygen and carbon. Boron oxide can be represented by the formula BₓO_{y}C_{z}, where x can range from about 0 to about 6, y can range from about 0 to about 3, and z can range from about 0 to about 3. In some cases, the boron oxycarbide may not include stoichiometric boron oxycarbide. In some cases, the boron oxycarbide can include other elements, such as carbon and/or hydrogen.

As used herein, “hydrogenated boron carbonitride” refers to a material that comprises hydrogen, boron, carbon and nitrogen. In some cases, the hydrogenated boron carbonitride may include other elements.

As used herein, “chemical vapor deposition”, abbreviated as “CVD”, refers to a method of depositing a film on a substrate by exposing its surface to one or more gaseous reactants, which react and/or decompose on the substrate surface to produce a desired film. Typically, CVD is performed by co-introducing the reactants into a reactor.

As used herein, “chemisorption” refers to an adsorption process, caused by a reaction on an exposed surface, which creates, for example, a covalent or ionic bond between the surface and the adsorbate.

As used herein, a “film” refers to a continuous, substantially continuous, or non-continuous material that extends in a direction perpendicular to a thickness direction to cover at least a portion of a surface. A film can include two-dimensional materials, three-dimensional materials, nanoparticles or even partial or full molecular layers or partial or full atomic layers or clusters of atoms and/or molecules. A film may be built up from one or more non-discernable layers (e.g., monolayers or sub-monolayers) to produce a uniform or a substantially uniform material, wherein the number of layers influences the thickness of the material.

As used herein, a “gas” refers to a state of matter consisting of atoms or molecules that have neither a defined volume nor shape. A gas includes vaporized solid and/or liquid and may be constituted by a single gas or a mixture of gases, depending on the context.

As used herein, a “plasma” refers to an ionized gas consisting of roughly equal numbers of negatively and positively charged species, generally electrons and ions. Excited and reactive species are also contained within the plasma, such as, for example, atoms and radicals, metastable atoms and molecules, and photons. A plasma discharge requires an externally imposed electric or magnetic field to ionize a gas. Plasma generation schemes and geometries, include, but are not limited to, capacitively coupled plasmas (CCPs), inductively coupled plasmas (ICPs), and RF-hollow cathode (HC) plasmas, which differ in their production of excited and reactive species and, as a result, they can provide very different fluxes of the various species.

As used herein, a “direct plasma generator” may refer to an active species generator configured to form and sustain plasma within a process chamber between a perforated faceplate of a showerhead injector and a substrate support of said process chamber, whereas a “remote plasma generator” may refer to an active species generator configured to form and sustain plasma within a process chamber such that an ion trap of said process chamber is arranged between said plasma and a substrate support of said process chamber. Further, a “remote plasma generator” may refer to an active species generator configured to form and sustain plasma outside of a process chamber and to introduce active species formed in said plasma into said process chamber, for example, via an active species duct or channel.

As used herein, a “precursor” refers to a compound that participates in a chemical reaction to form another compound or element, wherein a portion of the precursor (an element or group within the precursor) is incorporated into the compound or element that results from the chemical reaction. The compound or element that results from the chemical reaction may be a layer and/or a film that is formed on a surface of a substrate. As used herein, “silicon carbide” or “SiC” refers to a material that includes silicon and carbon. In some embodiments, silicon carbide may not include significant proportions of elements other than silicon and carbon. Silicon carbide may be represented by the formula SiC. In some embodiments, the silicon carbide comprises SiC. In some embodiments, the silicon carbide may consist essentially of SiC. Silicon carbide need not necessarily be a stoichiometric composition. An amount of silicon can range from 5% to 50%; an amount of carbon can range from about 50% to about 95%. In some embodiments, SiC films may comprise one or more elements in addition to silicon and carbon, such as hydrogen and/or nitrogen.

As used herein, “silicon carbonitride” or “SiₓC_{y}N_{z}” or “SiCN” refers to a material that comprises silicon, carbon, and nitrogen. Silicon carbonitride may be represented by the formula SiₓC_{y}N_{z}. In some embodiments, the silicon carbonitride may comprise more Si—N bonds than Si—C bonds, for example, a ratio of Si—N bonds to Si—C bonds may be from about 1:10 to about 10:1. In some embodiments, the silicon carbonitride films may comprise from about 0% to about 50% carbon on an atomic basis. In some embodiments, the silicon carbonitride may comprise from about 0.1% to about 40%, from about 0.5% to about 30%, from about 1% to about 30%, or from about 5% to about 20% carbon on an atomic basis. In some embodiments, the silicon carbonitride may comprise from about 0% to about 70% nitrogen on an atomic basis. In some embodiments, the silicon carbonitride may comprise from about 10% to about 70%, from about 15% to about 50%, or from about 20% to about 40% nitrogen on an atomic basis. In some embodiments, the silicon carbonitride may comprise about 0% to about 50% silicon on an atomic basis. In some embodiments, the silicon carbonitride may comprise from about 10% to about 50%, from about 15% to about 40%, or from about 20% to about 35% silicon on an atomic basis. In some cases, the silicon carbonitride may include other elements, such as hydrogen. The silicon carbonitride may include silicon carbide and silicon nitride.

As used herein, “silicon oxycarbide” or “Si_{z}OₓC_{y}” or “SiOC” refers to material that comprises silicon, oxygen, and carbon. As used herein, unless stated otherwise, SiOC is not intended to limit, restrict, or define the bonding or chemical state, for example, the oxidation state of any of Si, O, C, and/or any other element in the film. In some embodiments, the Si_{z}OₓC_{y} may comprise Si—C bonds and/or Si—O bonds. In some embodiments, the SiOC may comprise Si—C bonds and Si—O bonds and may not comprise Si—N bonds. In some embodiments, the SiOC may comprise Si—H bonds in addition to Si—C and/or Si—O bonds. In some embodiments, the SiOC may comprise more Si—O bonds than Si—C bonds, for example, a ratio of Si—O bonds to Si—C bonds may be from about 1:10 to about 10:1. In some embodiments, the SiOC may comprise from about 0% to about 50% carbon on an atomic basis. In some embodiments, the SiOC may comprise from about 0.1% to about 40%, from about 0.5% to about 30%, from about 1% to about 30%, or from about 5% to about 20% carbon on an atomic basis. In some embodiments, the SiOC may comprise from about 0% to about 70% oxygen on an atomic basis. In some embodiments, the SiOC may comprise from about 10% to about 70%, from about 15% to about 50%, or from about 20% to about 40% oxygen on an atomic basis. In some embodiments, the SiOC may comprise about 0% to about 50% silicon on an atomic basis. In some embodiments, the SiOC films may comprise from about 10% to about 50%, from about 15% to about 40%, or from about 20% to about 35% silicon on an atomic basis. In some embodiments, silicon oxycarbide can be represented by the chemical formula Si_{z}OₓC_{y}, where z can range from about 0 to about 2, x can range from about 0 to about 2, and y can range from about 0 to about 5.

As used herein, “silicon oxycarbonitride” or “Si_{z}OₓC_{y}N_{w}” or “SiOCN” refers to material that comprises silicon, oxygen, nitrogen, and carbon. As used herein, unless stated otherwise, SiOCN is not intended to limit, restrict, or define the bonding or chemical state, for example, the oxidation state of any of Si, O, C, N and/or any other element in the material. In some embodiments, SiOCN is material that can be represented by the chemical formula Si_{z}OₓC_{y}N_{w}, where z can range from about 0 to about 2, x can range from about 0 to about 2, y can range from about 0 to about 2, and w can range from about 0 to about 2.

As used herein, a “substituent” refers to an atom or a group of atoms that replaces one or more atoms (such as a hydrogen atom) or a group of atoms in a parent compound, thereby becoming a moiety in the resultant new compound. The substituent is substituted for the original atom or a group of atoms in the parent molecule. For simplicity, a substituent may be indicated in a chemical formula as an “R” group and each “R” group in a compound may be independently selected. Examples of substituent groups include, but are not limited to: a hydrogen atom (H), an “alkyl group”, such as saturated linear or branched C₁ to C₁₀ hydrocarbons, preferably C₁ to C₆ hydrocarbons (e.g., methyl, ethyl, propyl, iso-propyl, butyl, i-butyl, s-butyl, t-butyl, pentyl, 3-pentyl, neo-pentyl, and hexyl); a “cycloalkyl group”, such as C₃ to C₆ cyclic hydrocarbons (e.g., cyclopropyl, cyclobutyl, cyclopentyl, and cyclohexyl); an “alkenyl group”, such as C₂ to C₆ linear or branched unsaturated hydrocarbons (e.g., vinyl, allyl, propenyl, butenyl, pentenyl, hexenyl, butadienyl, pentadienyl, hexadienyl, ethynyl, propargyl, butynyl, pentynyl, and hexynyl); an “aryl group”, such as a phenyl, benzyl, tolyl, xylyl, naphthyl, cyclopentadienyl, and methyl, dimethyl, or ethyl cyclopentadienyl groups; a hydroxy group (OH); an “alkoxy group”, such as a linear or branched C₁ to C₆ alcohol (e.g., hydroxymethyl, hydroxyethyl, hydroxypropyl, hydroxybutyl, hydroxypentyl, and hydroxyhexyl); an “alkoxycarbonyl group”, such as a linear or branched C₁ to C₆ carbonyl hydrocarbon (e.g., methoxycarbonyl, ethoxycarbonyl, propoxycarbonyl, isopropoxycarbonyl, butoxycarbonyl, pentoxycarbonyl, and hexyloxycarbonyl); a thiol group (SH); an “alkylthiol group”, such as a linear or branched C₁ to C₆ thiol (e.g., thiolmethyl, thiolethyl, thiolpropyl, thiolbutyl, thiolpentyl, and thiolhexyl); a halide (X), such as fluoride (F), chloride (Cl), bromide (Br), and iodide (I); and an “haloalkyl group”, such as a linear or branched C₁ to C₆ alkylhalide having one or more halogen atoms (e.g., iodomethyl, bromomethyl, chloromethyl, fluoromethyl, trifluoromethyl, 2-chloroethyl, 2-fluoroethyl, 2,2,2-trifluoroethyl, and pentafluoroethyl). A substituent group may, in and of itself, be substituted. For example, an alkoxy group is a substituted alkyl group, where an H atom on the alkyl group is replaced with an OH group.

Articles “a” or “an” refer to a species or a genus including multiple species, depending on the context. As such, the terms “a/an”, “one or more” and “at least one” can be used interchangeably herein. It is also to be noted that the terms “comprising”, “including”, and “having” can be used interchangeably.

The term “about” generally refers to a range of numbers that is considered equivalent to the recited value (e.g., having the same function or result). In some instances, the term about may include numbers that are rounded to the nearest significant figure.

“At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Z₀).

It should be understood that every numerical range given throughout this disclosure is deemed to include the upper and the lower end points, and each and every narrower numerical range that falls within such broader numerical range, as if such narrower numerical ranges were all expressly written herein. By way of example, the phrase “from about 2 to about 4” or “from 2 to 4” includes 2 and 4 and the whole number and/or integer ranges from about 2 to about 3, from about 3 to about 4 and each possible range based on real (e.g., irrational and/or rational) numbers, such as from about 2.1 to about 3.9, from about 2.1 to about 3.4, and so on.

The present disclosure generally relates to methods for forming a radical treated film on the surface of substrate using radical enhanced atomic layer deposition and systems for performing such methods. Various aspects of the methods and systems and the benefits derived therefrom will now be described.

Fabricating modern semiconductor devices requires the accurate deposition of materials with carefully controlled thicknesses and compositions. Ideally, the desired material compositions could be deposited directly in a single-step process, but often this is not feasible and it becomes necessary to deposit a material layer and then convert it into a layer with the desired elemental composition and properties. Plasma treatments can be a way to achieve this conversion, but this approach is unsuitable for carbon-containing films, since any carbon present in the precursor molecules or the growing film is readily removed by the energetic components of a plasma discharge. In this regard, disclosed herein are methods and systems for fabricating a radical-treated film on the surface of a substrate using remote plasma. The methods and systems disclosed herein advantageously expand the availability of thin film materials that may not be readily fabricated using conventional processing methods. The disclosed method can be used to deposit and tune the elemental composition of thin film materials without the loss of easily reactive elements such as carbon. These and other advantages will be apparent from the disclosure of various aspects, embodiments, and configurations contained herein.

An aspect of the present disclosure is a method for forming a radical treated film on a surface of a substrate. The method comprises providing a substrate, and executing one or more super cycles. Individual super cycle comprises a deposition step and a radical treatment step. The deposition step comprises feeding precursor in vapor phase into a deposition chamber to deposit a film onto the substrate. The radical treatment step comprises generating a remote plasma, obtaining a radical flow from the remote plasma and exposing the substrate to the radical flow in a radical treatment chamber. The deposition chamber and the radical treatment chamber are operationally coupled to allow a substrate to be transferred between them without any air break.

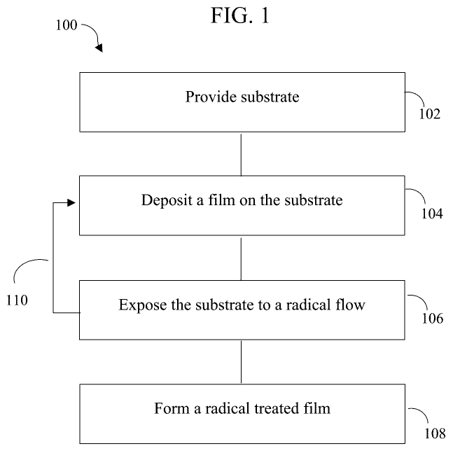

FIG. 1 is a process flow diagram 100 of an embodiment of the disclosure. In 102 a substrate is provided into a deposition chamber. A first precursor is introduced, and a film is deposited on a surface of the substrate 104. In some embodiments, step 104 may comprise introducing more than one precursor into the reaction chamber in vapor phase. The deposition may be performed by any vapor deposition method, such as atomic layer deposition, chemical vapor deposition, plasma enhanced atomic layer deposition or plasma enhanced chemical vapor deposition. The deposition temperature may be 40-550° C., and the chamber pressure may be 1-100 Torr. The deposited film may be a film comprising carbon. In addition to carbon the film may comprise other elements such as silicon or boron. In some embodiment, the deposited film comprises silicon, carbon, and nitrogen. In some embodiments the deposited film comprises silicon and carbon. In some embodiments, the deposited film comprises silicon, carbon and oxygen. In some embodiments, the deposited film comprises silicon, carbon, nitrogen and oxygen. In one embodiment, step 104 is repeated until a targeted film thickness is reached. In some embodiment, the deposited film comprises boron, carbon, and nitrogen. In some embodiments the deposited film comprises boron and carbon. In some embodiments, the deposited film comprises boron, carbon and oxygen. In some embodiments, the deposited film comprises boron, carbon, nitrogen and oxygen. In one embodiment, step 104 is repeated until a targeted film thickness is reached.

Next the substrate with the deposited film on its surface is exposed to a radical flow 106. The radical flow is obtained from a remote plasma which is generated by a plasma unit. The plasma is produced by gas-phase ionization of a reactive gas using radio frequency (RF) (e.g. 13.56 MHz or 27 MHz) plasma generator. In some embodiments, the reactive gas comprises nitrogen, hydrogen, oxygen or combinations thereof. The plasma from the plasma unit passes through an ion trap which traps the ions from the plasma so that mainly radicals pass though as a radical flow and reach the surface of the substrate. In some embodiments the ion trap is a mesh plate. In some embodiments the radical flow comprises nitrogen radicals, hydrogen radicals, oxygen radicals or combinations thereof. Typically, the RF power for generating the plasma is maintained between 50-1000 W.

Finally, a radical treated film is formed on the surface of the substrate 108. In one embodiment, the steps 104 and 106 can be repeated until a targeted film thickness is reached 110. The number of repeated cycles (n) is not particularly limited and may be between 1 and about 5,000. In some embodiments, the number of repeated cycles (n) is typically between 1 and about 2,000, between 1 and about 1,000, between 1 and about 500, between 1 and about 200, between 1 and about 100, or more typically between about 10 and about 1,000, more typically between about 10 and about 500, more typically between about 10 and about 200, more typically between about 10 and about 100, or even more typically between about 50 and about 1,000, even more typically between about 50 and about 500, or even more typically between about 50 and about 200. The number of repetitions of the deposition cycle (n) depends on the growth rate of the deposited material and the desired thickness of the film. In one embodiment, the substrate is exposed to a radical flow 106 after a certain number of deposition steps 104. For example, step 106 can be performed after 10 deposition cycles, or after 20 deposition cycles, or after 30 deposition cycles. The method and the individual process steps will be described in more detail below.

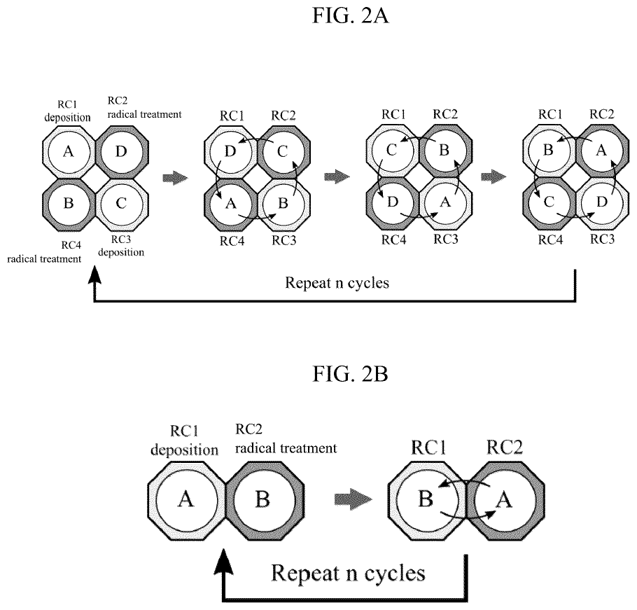

FIG. 2A illustrates a multi-process chamber module according to some embodiments. In some embodiments, the multi-process chamber module may comprise a quad-station arrangement comprising deposition stations (shown as RC1 and RC3 in FIG. 2A). The remaining two stations (shown as RC2 and RC4 in FIG. 2A) may comprise treatment stations, where substrates may be exposed to a radical flow. In some embodiments, more stations may be present in a multi-process chamber module. Generally, additional stations would include at least one additional deposition station and at least one additional treatment station.

As used herein, “station” refers broadly to a location that can contain a substrate so that a process may be performed on the substrate in the station. A station can thus refer to a reactor, or a portion of a reactor, or a reaction space or reaction chamber within a reactor. In some embodiments, stations in accordance with embodiments herein are in “gas isolation” from each other or are configured to be in gas isolation while a substrate is processed inside the station. In some embodiments, the stations are in gas isolation by way of physical barriers but not gas bearings or gas curtains. In some embodiments, the stations are in gas isolation by way of physical barriers in conjunction with gas bearings and gas curtains. In some embodiments, after or concurrently with the placement of a substrate in a particular station, that substrate is placed in gas isolation from the other stations (so that process steps can be performed in that station), and after the substrate has processed in the station, the station is brought out of gas isolation, and the substrate can be removed from the station and positioned in an intermediate space. Substrates from multiple different stations can be placed in a shared intermediate space for movement from station to station. The stations can be placed in gas isolation, for example, by a physical barrier. In some embodiments, the stations are not placed in gas isolation. In some embodiments, one or more stations comprise a heating and/or cooling system, so that different precursors in different stations can process substrates at different temperatures at the same time. As such, in some embodiments, an entire first station is at a lower or higher temperature than an entire second station, or a first station comprises a susceptor that is at a lower or higher temperature than a susceptor in a second station, and/or a first precursor is flowed into a first station while a second precursor is flowed into a second station at a lower or higher temperature than the first station.

In some embodiments, the stations are separated from each other by solid materials, and are not separated from each other by gas bearings or gas curtains. In some embodiments, the stations are separated from each other by solid materials or gas curtains and are not separated from each other by gas bearings. In some embodiments, the stations are separated from each other by solid materials or gas bearings and are not separated from each other by gas curtains. Optionally, the physical barrier can move in conjunction with a moving stage that shuttles substrates between the stations and the intermediate space, so that the physical barrier places the station in gas isolation at the same time (or slightly before or slightly after) the substrate is placed in that station. Optionally, the physical barrier can be used in conjunction with a gas barrier, for example to fill some gaps left by the physical barrier. In some embodiments, a physical barrier is provided, but a gas barrier or gas curtain is not.

In some embodiments, a station comprises a module or chamber of a reactor, so that each station comprises a separate chamber or module. In some embodiments, a station comprises a portion of a reaction chamber which can be placed in gas isolation from other portions of the reaction chamber by positioning a wall, a gas curtain or a gas bearing between the stations. Optionally, a given station is completely enclosed by one or more walls, gas curtains, gas bearings, or a combination of any of these items. However, in some embodiments, the stations are not separated.

As illustrated in FIG. 2A, during a process according to some embodiments herein, wafers may be rotated through the stations. For example, a wafer may enter the chamber at station RC1, at which the wafer may undergo a first deposition process. In some embodiments, after undergoing the first deposition process, the wafer may be transferred to RC4, as shown in FIG. 2A. Alternatively, the wafer may be transferred to RC2. In either case, the wafer may undergo a first treatment process, which may include exposure to a radical flow. After the first treatment process, the wafer may be transferred to RC3, where it may undergo a second deposition process. After undergoing the second deposition process, the wafer may be transferred to RC2 if it was previously transferred to RC4 or may be transferred to RC4 if it was previously transferred to RC2. In either case, the wafer may undergo a second treatment process that is similar to or the same as the first treatment process. The wafer may be transferred back to RC1 to complete a single deposition-treatment super cycle. The cycle may be repeated to achieve desired film quality and thickness. Furthermore, the wafer may enter the chamber at any one of RC1, RC2, RC3, or RC4 and cycle through the stations in any direction. Generally, however, the deposition-treatment super cycle will begin with at least one deposition process followed by at least one treatment process. The at least one flowable deposition process may be performed simultaneously on different wafers and/or performed sequentially on a single wafer. In the illustrated embodiment of FIG. 2A, deposition stations and treatment stations of the same type are positioned diagonally. In some embodiments, this configuration may improve film uniformity. However, neighboring placement of stations of the same type is also within the scope of the embodiments disclosed herein. In some embodiments, two or more pairs of stations perform the same process on two or more substrates in parallel.

The above cyclic concept can also be applied to different numbers of stations. For example, a dual chamber module as illustrated in FIG. 2B may have a first station (RC1) for performing a deposition and a second station (RC2) for performing a treatment process, and substrates may be transferred cyclically between the first station and the second station. Thus, in some embodiments, a multi-process chamber module as described herein can comprise multiple stations, half of which may be used for deposition and the other half of which may be used for treatment processes. In some embodiments, a multi-process chamber module comprises at least 2 stations, for example at least 2, 3, 4, 5, 6, 7, 8, 9, 10, 11, 12, 13, 14, 15, 16, 17, 18, 19, 20, 30, 40, 50, 100, 150, 200, 250, 300, 400, or 500 stations, including ranges between any two of the listed values. However, the number of stations is not necessarily limited.

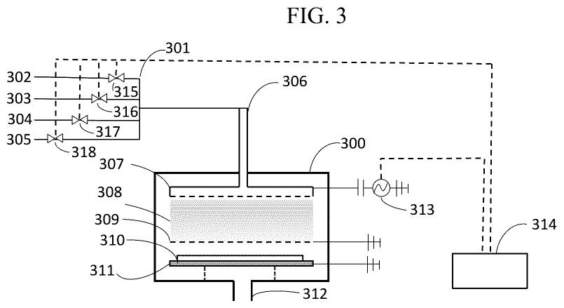

FIG. 3 shows an example of an embodiment of an apparatus where the plasma is formed in the upper portion of the reaction chamber 300, that is between the mesh plate 309 and the showerhead 307. A reactive gas is supplied from a first source 303, in the form of a gas, through the gas manifold 301 into the reaction chamber through the showerhead 307. The reactive gas may be vaporized and entrained in or pulsed into a carrier gas. The apparatus is also configured to allow for the introduction of other gasses (e.g., other precursors or reactive gasses, carrier, dilutant, process, feed, and/or purging gasses), either through the shower head 307 or from other ports (not shown) into the reaction chamber. Thus, the apparatus may comprise second and third sources, 304 and 305. Unreacted gasses and gaseous reaction by-products exit the reaction chamber through an exhaust line 312. The reaction chamber 300 may optionally be equipped with a purge line and/or a pump line coupled to a vacuum pump so that the reaction chamber may be purged between the various reaction cycles (not shown). An RF power source 313 is electrically connected to the showerhead 307, allowing for the showerhead to be biased relative to the susceptor 311, to form a plasma discharge between the two. An ion trap 309 may be positioned between the showerhead 307 and the wafer 310 to restrict the plasma zone 308 to upper portion of the chamber, above the ion trap. For example, an electrically grounded mesh plate may be used as an ion trap. In some embodiments, the mesh plate is a metal plate comprising hundreds of holes in a showerhead-like pattern that lets radical species pass through to the wafer 310 while trapping the ions. For instance, the mesh plate may comprise between about 1,000 to about 5,000 holes, each hole having a diameter between about 0.5 mm to about 2 mm. The addition of the ion trap, beneficially reduces or even eliminates interactions of electrons and ions with the wafer surface by restricting the plasma to the plasma zone 308 in the upper portion of the reaction chamber 300. The apparatus also comprises a controller 314 operably connected to the first, second, third, and fourth gas valves, 315-318, the RF power source 313, and other components (not shown). The controller 314 is configured and programmed to independently control (e.g., turn on and off, etc.) the supply of the various gasses (e.g., first precursor, reactive gas, and any dilutant, process, feed, and/or purging gasses etc.) and the RF power source 313, as required, to treat a film on the surface of the wafer 310. In some embodiments, the controller 314 is configured to open valve 315 to flow the carrier gas from the first carrier gas source 302 into the reaction chamber. It is further configured to open valve 316 to flow the reactive gas from the first source 303 into the reaction chamber and to turn on the RF power source 313 to form the plasma. Turning on the RF power 313 and opening valve 316 may be done one after the other, or simultaneously. After a set period of time, the controller 314 closes the valve to the reactive gas 316 and turns off the RF power source 313. The controller 314 is programed to repeat the various process steps to treat a film on the surface of the wafer 310. The controller 314 may be programed to perform other process steps in between these various steps.

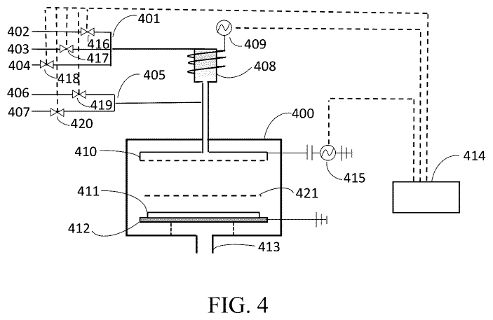

In another embodiment, the controller 314 is configured to open valve 315 to flow the carrier gas from the first carrier gas source 302 into the reaction chamber, then open valve 316 to flow the reactive gas from the first source 303 into the reaction chamber while turning on the RF power source 313 to form the plasma. Turning on the RF power 313 and opening valve 316 may be done one after the other, or simultaneously. After a set period of time, the controller 314 closes the valve to the first precursor 316 and turns off the RF power source 313. The controller 314 is programed to repeat the various process steps to treat a film on the surface of the wafer 310. The controller 314 may be programed to perform other process steps in between these various steps. FIG. 4 shows an example of an embodiment of a radical treatment chamber where the plasma is formed using a remote plasma unit (RPU) 408 upstream of the reaction chamber 400. Optionally, a second plasma source may be provided. For example, the second plasma source 415 may be electrically connected to a showerhead 410, allowing for the showerhead to be biased relative to the susceptor 412 to form a second plasma discharge between the two. A carrier gas is supplied from a first carrier gas source 402 through a gas manifold 401 and passed through the RPU 408 into the reaction chamber 400 through the showerhead 410 that is positioned directly above a susceptor 412 on which a wafer 411 (i.e., a planar substrate) is placed. The reactive gas may be vaporized and entrained in or pulsed into the carrier gas. The apparatus is also configured to allow for the flow of other gasses from an optional third source 404 through the RPU 408.

For example, in some instances, it may be beneficial to introduce a cleaning gas (e.g., NF₃ diluted in an inert gas) periodically or even between every reaction cycle to remove any deposition from decomposed precursor chemicals in one or more of the gas lines, the gas manifold 401, RPU 408, and the showerhead 410. Additional gasses from a second source 406 (e.g., carrier, dilutant, process, feed, and/or purge gasses), may flow from a second gas manifold 405 through the showerhead 410 or from other ports (not shown) into the reaction chamber 400. Unreacted gasses and gaseous reaction by-products exit from the bottom of the reaction chamber through an exhaust line 413. The reaction chamber may optionally be equipped with a purge line and/or a pump line coupled to a vacuum pump so that the chamber may be purged between the various reaction cycles (not shown). The apparatus also comprises a controller 414 operably connected to the first, second, and third gas valves 416-418 on the first gas manifold 401, the first and second gas valves 419 and 420 on the second gas manifold 405, the RF power source for the RPU 409, the second optional RF power source 415, and other components (not shown). Optionally, the apparatus further comprises an ion trap 421 which may be positioned between the showerhead 410 and the wafer 411 to restrict the plasma zone to the upper portion of the chamber, above the ion trap. For example, an electrically grounded mesh plate may be used as an ion trap. In some embodiments, the mesh plate is a metal plate comprising hundreds of holes in a showerhead-like pattern that lets radical species pass through to the wafer 411 while trapping the ions. For instance, the mesh plate may comprise between about 1,000 to about 5,000 holes, each hole having a diameter between about 0.5 mm to about 2 mm. The addition of the ion trap, beneficially reduces or even eliminates interactions of electrons and ions with the wafer surface by restricting the plasma to the plasma zone in the upper portion of the reaction chamber 400.

The controller 414 is configured and programmed to independently control (e.g., turn on and off, etc.) the supply of the various gasses (e.g., carrier gas, reactive gas, and any dilutant, process, feed, and/or purging gasses etc.), the plasma source, and optionally the second plasma source, as required, to treat a film on the surface of the wafer 412 with a radical flow. For example, in some embodiments, the controller 414 opens the valve 419 to flow the reactive gas from the second source 406 into the reaction chamber 400 and turn on the RF power supply 409 in the RPU. After a set period of time, the controller 414 turns off the RF power supply 409. After a set period of time, the controller 414 closes the valve 419 to the reactive gas 406. The controller 414 is programed to repeat the various process steps to treat a film on the surface of the wafer 411 with a radical flow. The controller 414 may be programed to perform other process steps in between these various steps.

The semiconductor processing apparatus or system disclosed herein can include additional sources and additional components, which are not shown in FIG. 4, such as those typically found on semiconductor processing apparatus. For example, the semiconductor processing apparatus may be provided with one or more heaters and one or more temperature regulators to activate the reactions by elevating the temperature of one or more of the substrate and/or gasses entering into the reaction chamber (e.g., carrier gas, precursor, reactive gas, etc.). The semiconductor processing apparatus may also be provided with a pumping system to purge the reaction chamber in between the various processing steps.

The radical treatment and deposition chambers can form part of an ALD assembly and may be a single wafer reactor or it may comprise one or more multi-station deposition chambers. Alternatively, the reactor may be a batch reactor. The various steps of the method can be performed within a single reaction chamber, or they can be performed in multiple reaction chambers, such as reaction chambers of a cluster tool. In some embodiments, the method is performed in a single reaction chamber of a cluster tool, but other, preceding or subsequent, manufacturing steps of the structure or device are performed in additional reaction chambers of the same cluster tool. Optionally, an assembly including the reaction chamber can be provided with a heater to activate the reactions by elevating the temperature of one or more of the substrate, the reactants, the precursors, and other gasses. The reactants, precursors, and other gasses may be introduced into the chamber using a showerhead-type reaction chamber or cross-flow reaction chamber, or a combination thereof.

The above discussion has been provided for purposes of illustration using a two-step cycle. The illustrated twostep cycle is sufficient to explain the disclosed method, but the skilled artisan will appreciate that the principles and advantages of the embodiments taught herein can be readily extended to more complex ALD processes. The skilled artisan will readily appreciate that each cycle can include additional steps (e.g., a third reactant pulse, fourth reactant pulse, etc., can be introduced), or of the same reactants, and that not all cycles need to be identical (e.g., a third reactant can be introduced every five cycles to incorporate a desired percentage of different elements). Such flexibility is provided and allows for a variety of films to be produced without departing from the spirit of the disclosure.

The methods and systems disclosed herein may be used to deposit a number of films, such as, by way of non-limiting example, silicon (Si) containing films and boron (B) containing films. The methods and systems disclosed herein may be used to modify the elemental composition of a number of films, such as, by way of non-limiting example, silicon (Si) containing films and boron (B) containing films. In one embodiment, the methods and systems disclosed herein may be used to modify the elemental composition of films containing carbon. The first precursor may comprise one or more of silicon and boron. Suitable precursors may include those which are known to be useful in ALD, PEALD, CVD or PECVD processes. In some embodiments, the first precursor may be useful in CVD-type deposition processes, but it may be unreactive in ALD-type deposition processes or vice versa.

The methods and systems disclosed herein may be used to deposit silicon (Si) containing films, such as, by way of non-limiting example, low dielectric constant (k) films, high k gate silicates, low temperature silicon epitaxial films, and films comprising silicon oxycarbonitride, silicon carbonitride, silicon carbide and silicon oxycarbide. In some embodiments the Si-containing film is selected from the group consisting of silicon oxycarbonitride, silicon carbonitride, silicon carbide, silicon oxycarbide, and combinations thereof. In some embodiments, the Si-containing film is selected from the group consisting of silicon oxycarbonitride, silicon carbonitride, and combinations thereof. In these embodiments, the first precursor comprises silicon. In some embodiments, the first precursor comprises silicon and may further comprise one more of carbon (C), hydrogen (H), nitrogen (N), oxygen (O), and halogen (X, where X may be a fluorene (F), chlorine (Cl), bromine (Br) or iodine (I)). The silicon-containing precursor may comprise one or more Si—C bond(s), Si—H bond(s), Si—N bond(s), Si—O bond(s), and Si—X bond(s). Suitable silicon-containing precursors may be selected from a silane, a halosilane, an aminosilane, a silicon alkoxide, a siloxane, and a combination thereof.

In some embodiments, the silicon-containing precursor is a silane. A silane contains silicon and hydrogen and may optionally also comprise one or more carbon, oxygen, nitrogen, and halogen atoms. Examples of silanes include monosilanes (SiH₄₋ₙ(R)ₙ, where n is an integer from 0 to 4), disilanes (S₂H₆₋ₙ(R)ₙ, where n is an integer from 0 to 6), and trisilane (S₃H₈₋ₙ(R)ₙ, where n is an integer from 0 to 8) and so on, where each R is an independently selected substituent, preferably an alkyl group or aryl group. Examples of suitable silane precursors are silane (SiH₄), disilane (Si₂H₆), and organo silanes such as dimethylsilane (H₂Si(CH₃)₂), diethylsilane (H₂Si(C₂H₅)₂), trimethylsilane (HSi(CH₃)₃), and triethylsilane (HSi(C₂H₅)₃), and the like. In some embodiments, the silicon-containing precursor is a halosilane. A halosilane contains at least one halogen atom bonded to a silicon atom (Si—X) and may also optionally comprise one or more hydrogen, carbon, oxygen, and nitrogen atoms. Examples of halosilanes include halosilanes, halodisilanes (Si—Si), halotrisilane (Si—Si—Si), and so on. Examples of suitable halosilane precursors are dichlorosilane (SiH₂Cl₂), dibromosilane (SiH₂Br₂), diiodosilane (SiH₂I₂), hexachlorodisilane (Si₂Cl₆), and octachlorotrisilane (Si₃Cl₈), and the like.

In some embodiments, the silicon-containing precursor is an aminosilane. An aminosilane (or silylamine) includes at least one nitrogen atom bonded to a silicon atom (Si—N) and carbon and/or hydrogen and may also optionally comprise one or more oxygen and halogen atoms. Examples of aminosilanes include mono-, di-, tri- and tetra-aminosilanes (e.g., H₃Si(NH₂), H₂Si(NH₂)₂, HSi(NH₂)₃, and Si(NH₂)₄, respectively), silazanes (e.g., NH(SiH₃)₂) and trisilylamines (e.g., N(SiH₃)₂)) as well as substituted linear and cyclic derivatives thereof, wherein one or more hydrogen atoms on the amino group and/or the silane group are independently substituted with a substituent group (R), preferably an alkyl group or aryl group. Examples of aminosilane precursors are bis(diethylamino)silane (C₈H₂₀N₂Si), bis(diethylamino)dimethylsilane (C₁₀H₂₆N₂Si), di-isopropylaminosilane (C₆H₁₇NSi), N-(diethylaminosilyl)-N-ethylethanamine (C₈H₂₂N₂Si), hexamethylcyclotrisilazane (C₆H₂₁N₃Si₃), hexamethyldisilazane (C₆H₁₉NSi₂) and the like.

In some embodiments, the silicon-containing precursor is a silicon alkoxide. A silicon alkoxide includes at least one Si—O—C linkage and may also optionally comprise one or more hydrogen, nitrogen, and halogen atoms. Examples of silicon alkoxide include mono-, di-, tri- and tetra-silicon alkoxide (e.g., H₃Si(OCH₃), H₂Si(OCH₃)₂, HSi(OCH₃)₃, and Si(OCH₃)₄, respectively) as well as substituted linear and cyclic derivatives thereof wherein one or more hydrogen atoms on the methyl group and/or the silane group are independently substituted with a substituent group (R), prefer an alkyl group or an aryl group. Examples of silicon alkoxide precursors are tetraethylorthosilicate (TEOS, Si(OC₂H₅)₄), dimethoxydimethylsilane (Si(OCH₃)₂(CH₃)₂), and trimethoxymethylsilane (Si(OCH₃)₃CH₃), methoxypropyltrimethoxysilane (Si(OCH₃)₃C₃H₆OCH₃) and the like. In some embodiments, the silicon-containing precursor is a siloxane. A siloxane includes at least one Si—O—Si linkage, and may optionally also contain one or more hydrogen, carbon, and halogen atoms. Examples of siloxane include linear and cyclic siloxanes, such as cyclotrisiloxanes, cyclotetrasiloxanes, and silsesquioxanes. Examples of suitable siloxane precursors include octamethylcyclotetrasiloxane (OMCTS, C₈H₂₄O₄Si₄), 1,1,3,5,5,7-hexamethylcyclotetrasiloxane (HMCTS, C₈H₂₄O₃Si₄), 1,3,5,7-tetramethyl-cyclotetrasiloxane (TMCTS, C₄H₁₆O₄Si₄), and the like.

In some embodiments, the silicon containing precursor is selected from the group consisting of dimethylsilane, diethylsilane, trimethylsilane, triethylsilane, dichlorosilane, diiodosilane, hexachlorodisilane, octachlorotrisilane bis(diethylamino)silane, bis(diethylamino)dimethylsilane diisopropylaminosilane, N-(diethylaminosilyl)-N-ethylethanamine, hexamethylcyclotrisilazane, tetraethylotrhosilicate, dimethoxydimethylsilane, trimethoxymethylsilane, octamethylcyclotetrasiloxane, 1,1,3,5,5,7-hexamethylcyclotetrasiloxane, 1,3,5,7-tetramethylcyclotetrasiloxane, and combinations thereof.

The methods and systems disclosed herein may be used to deposit boron (B) containing films, such as, by way of non-limiting example, hard masks, low dielectrics, lining layers, boron-doped films (e.g., borosilicate glass), and films comprising boron nitride, boron carbide, borocarbonitride, and boron oxide. In some embodiments, the boron-containing film is selected from the group consisting of boron carbide, borocarbonitride, hydrogenated boron carbide, hydrogenated borocarbonitride, and combinations thereof. In these embodiments, the first precursor comprises boron. In some embodiments, the first precursor comprises boron and may further comprise one more of carbon (C), hydrogen (H), nitrogen (N), and oxygen (O). The boron-containing precursor may comprise one or more B—C bond(s), B—H bond(s), B—N bond(s), and B—O bond(s). Suitable boron-containing precursors may be selected from a borane, an alkyl borane, an aryl borane, a carborane, an amine or amino borane, a borate ester, a borazine, and a combination thereof.

In some embodiments, the boron-containing precursor is a borane (BₓH_{Y}). Examples of suitable borane precursors are diborane (B₂H₆), tetraborane (B₄H₁₀), pentaborane (B₅H₉), decaborane (B₁₀H₁₄), octadecaborane (B₁₈H₂₂), and the like. In some embodiments, the borane precursor is substituted with one or more alkyl group(s), aryl group(s), and combinations thereof. For example, one or more hydrogen atoms in a borane may be substituted with an alkyl group and/or an aryl group. Examples of suitable alkyl and aryl borane precursors include trimethyl borane (B(CH₃)₃), triethyl borane (B(C₂H₅)₃), triphenyl borane (B(C₆H₅)₃), and the like.

In some embodiments, the boron-containing precursor is a carborane. A carborane contains boron, carbon, and hydrogen and may optionally be substituted with one or more oxygen, nitrogen, and halogen atoms. Examples of suitable carborane precursors are nido-carborane (C₂B₄H₈), ortho-carborane (C₂B₁₀H₁₂), and the like. In some embodiments, the boron-containing precursor is an amine or amino borane. Examples of amine boranes include ammonia borane (NH₃BH₃) and substituted derivatives thereof (e.g., NRₙH₃₋ₙBH₃, where n is an integer from 1 to 3 and each R is independently a substituent group, preferably an alkyl group or an aryl group). Examples of amino boranes include mono-, di-, tri-amino borane (e.g., H₂B(NH₂), HB(NH₂)₂, and B(NH₂)₃, respectively) and linear and cyclic substituted derivatives thereof (e.g., H₂B(NHR), H₂B(NR₂), HB(NHR)₂, HB(NR₂)₂, B(NHR)₃, and B(NR₂)₃, where each R is independently a substituent group, preferably an alkyl group or an aryl group). Examples of suitable amine and amino borane precursors are ammonia borane (NH₃BH₃), methylamine borane (CH₃NH₂BH₃), dimethylamine borane ((CH₃)₂NHBH₃), trimethylamine borane ((CH₃)₃NBH₃), t-butylamine borane ((CH₃)₃CNH₂BH₃), tris(dimethylamino)borane B(N(CH₃)₂)₃, B-(cycloriborazanyl)amine borane (B₄N₄H₁₆), and the like.

In some embodiments, the boron-containing precursor is a borate ester. Examples of borate esters include ortho borates such as borinic esters (BR₂(OR)), boronic esters (BR₂(OR)), and borates (B(OR)₃) and metaborates (B₃O₃(OR)₃), where each R is independently a substituent group, preferably an alkyl group or an aryl group. Examples of suitable borate ester precursors are trimethyl borate (B(OCH₃)₃, triethyl borate (B(OCH₂CH₃)₃, and the like. In some embodiments, the boron-containing precursor is borazine or a substituted borazine. Borazine has the chemical structure B₃H₆N₃. In substituted borazines one or more H atoms are replaced with a substituent group (R), preferably an alkyl group or an aryl group. Additionally, or alternatively, one or more boron or nitrogen atoms in the borazine ring may be substituted with a carbon atom. Examples of suitable borazine precursors are borazine (B₃H₆N₃), 2,4,6-trichloroborazine (B₃H₃Cl₃N₃), 2,4,6-tribromoborazine (B₃H₃Br₃N₃), diborazine (C₃B₂H₃N), and the like. In some embodiments, the boron containing precursor is selected from the group consisting of nido-carborane, ortho-carborane, ammonia borane, dimethylamine borane, trimethylamine borane, t-butylamine borane, tris(dimethylamino)borane, B-(cycloriborazanyl)amine borane, trimethyl borate, triethyl borate, borazine, 2,4,6-trichloroborazine, 2,4,6-tribromoborazine, diborazine, and combinations thereof.

Plasma is generated using a reactive gas to form radicals and/or excited species which react with the deposited layer on the surface of the substrate. In some embodiments, the reactive gas in the remote plasma is selected from the group consisting of: an oxygen containing gas, a nitrogen containing gas, a hydrogen containing gas, and combinations thereof. In some embodiments, the reactive gas may comprise ammonia gas or nitrous oxide. As the reactive gas is formed into radicals, this can in other words be called a radical flow. The radical flow comprises one or more of oxygen radicals, nitrogen radicals, hydrogen radicals and combinations thereof. In some embodiments, the radical flow can comprise ammonia radicals or nitrous oxide radicals.

The methods and systems disclosed herein can provide several benefits, including enhanced control over the elemental composition of the deposited film material. It may also provide a method for obtaining conformal films of carbon-containing oxide or nitride materials. The methods and systems may also enable the fabrication of such films in an efficient manner that increases throughput and avoids exposing the film material to impurities such as moisture.

Although certain embodiments and examples are disclosed herein, it will be understood by those skilled in the art that the disclosed methods and systems extend beyond the specifically disclosed embodiments and include all novel and nonobvious combinations and sub-combinations of the various processes, systems, and configurations, as well as any and all equivalents thereof. It is to be understood that the methods and/or systems described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases. Moreover, various features of the disclosure are grouped together in one or more, aspects, embodiments, and configurations for the purpose of streamlining the disclosure. The features of the aspects, embodiments, and configurations of the disclosure may be combined in alternate aspects, embodiments, and configurations other than those discussed above. The methods and systems of disclosure are not to be interpreted as reflecting an intention that the claimed disclosure requires more features than are expressly recited in each claim. Rather, as the following claims reflect, inventive aspects lie in less than all features of single foregoing disclosed aspects, embodiments, and configurations. Thus, the following claims are hereby incorporated into this Detailed Description, with each claim standing on its own as a separate preferred embodiment of the disclosure.

1. A method for forming a radical treated film on a surface of a substrate, comprising:
a. providing a substrate; and
b. executing one or more super cycles, individual super cycles comprising a deposition step and a radical treatment step; wherein the deposition step comprises feeding a precursor in vapor phase into a deposition chamber to deposit a film onto the substrate;
wherein the radical treatment step comprises generating a remote plasma, obtaining a radical flow from the remote plasma, and exposing the substrate to the radical flow in a radical treatment chamber; and
wherein the deposition chamber and the radical treatment chamber are operationally coupled to allow a substrate to be transferred between them without any air break.

2. The method according to claim 1, wherein the radical treated film comprises carbon.

3. The method according to claim 1, wherein the deposition step comprises a plurality of deposition cycles.

4. The method according to claim 1, wherein the radical flow is obtained from the remote plasma with an ion trap.

5. The method according to claim 4, wherein an ion trap is provided in the reaction chamber between the remote plasma discharge and the substrate.

6. The method according to claim 4, wherein the ion trap is an electrically grounded mesh plate.

7. The method of claim 5, wherein the remote plasma discharge is produced by gas-phase ionization of a gas with a radio frequency (RF) power of 500 W or less.

8. The method of claim 5, wherein the remote plasma discharge is produced by gas-phase ionization of a gas with a radio frequency (RF) power of 100 W or less.

9. The method according to claim 1, wherein a temperature of the substrate is at least 40° C. and no more than 550° C.

10. The method according to claim 1, wherein a temperature of the substrate is at least 75° C. and no more than 400° C.

11. The method according to claim 1, wherein the precursor comprises silicon.

12. The method of claim 11, wherein the precursor is selected from the group consisting of: a silane, an alkyl silane, a halosilane, an aminosilane, a silicon alkoxide, a siloxane, a silazane, and combinations thereof.

13. The method of claim 11, wherein the precursor is selected from the group consisting of: silane, disilane, trisilane, dimethylsilane, diethylsilane, trimethylsilane, triethylsilane, dichlorosilane, diiodosilane, hexachlorodisilane, octachlorotrisilane bis(diethylamino)silane, bis(diethylamino)dimethylsilane, diisopropylaminosilane, N-(diethylaminosilyl)-N-ethylethanamine, hexamethylcyclotrisilazane, tetraethylotrhosilicate, dimethoxydimethylsilane, trimethoxymethylsilane, tetramethylcyclotetrasiloxane, octamethylcyclotetrasiloxane, 1,1,3,5,5,7-hexamethylcyclotetrasiloxane, 1,3,5,7-tetramethylcyclotetrasiloxane, bis(diethoxysilyl)ethane, methoxypropyltrimethoxysilane, and combinations thereof.

14. The method of claim 1, wherein the precursor comprises boron.

15. The method of claim 1, wherein the precursor is selected from the group consisting of: a borane, an alkyl borane, an aryl borane, a carborane, an amine borane, an amino borane, a borate ester, a borazine, triethylboron and combinations thereof.

16. The method of claim 1, wherein the precursor is selected from a group consisting of: nido-carborane, ortho-carborane, ammonia borane, dimethylamine borane, trimethylamine borane, t-butylamine borane, tris(dimethylamino)borane, bromobis(diethylamino)borane, bromobis(dimethylamino)borane, triethyl boron, boron triiodide, boron tribromide, B-(cycloriborazanyl)amine borane, trimethyl borate, triethyl borate, borazine, 2,4,6-trichloroborazine, 2,4,6-tribromoborazine, diborazine, and combinations thereof.

17. The method of claim 1, wherein the remote plasma comprises a reactive gas, wherein the reactive gas in the remote plasma is selected from the group consisting of: an oxygen containing gas, a nitrogen containing gas, a hydrogen containing gas, and combinations thereof.

18. The method of claim 1, wherein the radical flow comprises one or more of oxygen radicals, nitrogen radicals, hydrogen radicals, or combinations thereof.

19. The method of claim 1, wherein the radical treated film is selected from the group consisting of: silicon oxycarbonitride, silicon carbonitride, silicon carbide, silicon oxycarbide, and combinations thereof.

20. The method of claim 1, wherein the radical treated film is selected from the group consisting of: boron carbide, boron carbonitride, boron oxycarbide, hydrogenated boron carbonitride, and combinations thereof.

21. The method of claim 1, wherein the radical treated film is selected from the group consisting of: silicon oxycarbonitride, silicon oxycarbide, silicon carbonitride, boron carbonitride, hydrogenated boron carbonitride, and combinations thereof.

22. A semiconductor processing apparatus comprising:
one or more process chambers, each process chamber comprising two or more stations, each station comprising an upper compartment and a lower compartment,
wherein the upper compartment is configured to contain a substrate during processing of the substrate;
wherein the lower compartment comprises a shared intermediate space between the two or more stations;
a first transfer system configured to move a substrate from a first process chamber to a second process chamber in a wafer handling chamber;
a second transfer system configured to move the substrate from a first station to a second station within the shared intermediate space of a process chamber;
a first heating unit configured to control a first station temperature independently of a second station temperature;
a pressure system comprising a pump and exhaust, the pressure system configured to maintain a common process chamber pressure in the two or more stations; and
a controller comprising a processor that provides instructions to the apparatus to control a cycle of:
(a) placing a substrate in a first station;
(b) depositing a film on the substrate in the first station by a vapor deposition process;
(c) after depositing the film on the substrate, placing the first substrate in the second station;
(d) performing a radical treatment on the substrate by supplying a radical flow to the station to form a modified film; and
repeating (a)-(d) in a cycle until a film of desired thickness is deposited on the substrate.

23. A method for film deposition, the method comprising:
(a) placing a substrate in a first station, the first station comprising an upper chamber and a lower chamber, wherein the lower chamber comprises a shared intermediate space between the first station, a second station, a third station, and a fourth station;
(b) contacting the substrate in the first station with a precursor, wherein the contacting with the precursor forms a first film layer on the first substrate;
(c) after contacting the substrate in the first station with the precursor, placing the substrate in the second station;
(d) performing a first radical treatment on the substrate by contacting the surface of the first film layer with a radical flow;
(e) after performing the first radical treatment on the substrate, placing the substrate in the third station;
(f) contacting the substrate in the third station with the precursor, wherein the contacting with the precursor forms a second film layer on the first substrate;
(g) after contacting the substrate in the third station with the precursor, placing the substrate in the fourth station;
(h) performing a second radical on the substrate by contacting the surface of the second film layer with a radical flow; and
repeating (a)-(h) in a cycle until a film of desired thickness is deposited on the first substrate.
